(19) United States
(12) Patent Application Publication
(10) Pub. No.: US 2024/0297047 A1
(43) Pub. Date: Sep. 5, 2024

(54) MANUFACTURING METHOD OF SEMICONDUCTOR STRUCTURE

(71) Applicant: Winbond Electronics Corp., Taichung City (TW)

(72) Inventors: Kun-Che Wu, Taichung City (TW); Tsung-Wei Lin, Taichung City (TW); Chungchen Hsu, Taichung City (TW)

(73) Assignee: Winbond Electronics Corp., Taichung City (TW)

(21) Appl. No.: 18/592,416

(22) Filed: Feb. 29, 2024

(30) Foreign Application Priority Data
Mar. 3, 2023 (TW) 112107803

(51) Int. Cl. H01L 21/308; H01L 21/027

(52) U.S. Cl. CPC H01L 21/3086; H01L 21/0274; H01L 21/3081

(57) ABSTRACT

A manufacturing method of a semiconductor structure includes the following steps. A substrate is provided. A material layer is formed on the substrate. A first hard mask pattern is formed on the material layer. The top-view pattern of the first hard mask pattern is ring-shaped. The first hard mask pattern has an opening. A second hard mask pattern is formed on the first hard mask pattern. The second hard mask pattern fills the opening. The top-view pattern of the second hard mask pattern is completely located inside the outer contour of the top-view pattern of the first hard mask pattern. The pattern of the first hard mask pattern and the pattern of the second hard mask pattern are transferred to the material layer to form a first target pattern.

### CROSS-REFERENCE TO RELATED APPLICATION

This application claims the priority benefit of Taiwan application serial no. 112107803, filed on Mar. 3, 2023. The entirety of the above-mentioned patent application is hereby incorporated by reference herein and made a part of this specification.

### BACKGROUND

### Technical Field

The present disclosure relates to a method for manufacturing a semiconductor structure, and in particular relates to a method for manufacturing a semiconductor structure using lithography-etching-lithography-etching technique.

### Description of Related Art

During some processes of manufacturing semiconductor structures, layers of material are patterned to form a target pattern. In order to achieve high pattern density and gradually shrinking line width, some known semiconductor structures are fabricated using double patterning technique, such as Litho-Etch-Litho-Etch (LELE). LELE, also known as pitch splitting, performs two separate lithography and etch steps to define the target pattern, thereby doubling the pattern density. In detail, in the early stage of LELE, the layout patterns that could not be produced through a single step of exposure were disassembled to form two layout patterns with low pattern density, and then made into two masks. Then, two separate exposure steps and two separate etch steps are taken to form two rougher patterns, which are then combined and superimposed to form the initially required high-density layout pattern.

However, due to the limitations of the lithography process, in the target pattern formed by LELE, a concave contour corresponding to the overlapping position of the two rougher patterns is easily formed. When the target pattern is a conductive structure, the concave contour will lead to an increase in contact resistance, and even affect the operation of the semiconductor device. Therefore, how to develop a manufacturing method that may produce a semiconductor structure that meets the expected target pattern is a goal to be achieved with continuous efforts.

### SUMMARY

The disclosure provides a method for manufacturing a semiconductor structure, which is able to make the target pattern formed through a patterning process that meets expectations.

The disclosure provides a method for manufacturing a semiconductor structure, which includes the following steps. A substrate is provided. A material layer is formed on the substrate. A first hard mask pattern is formed on the material layer. The top-view pattern of the first hard mask pattern is ring-shaped. The first hard mask pattern has an opening. A second hard mask pattern is formed on the first hard mask pattern. The second hard mask pattern fills the opening. The top-view pattern of the second hard mask pattern is completely inside the outer contour of the top-view pattern of the first hard mask pattern. The pattern of the first hard mask pattern and the pattern of the second hard mask pattern are transferred to the material layer to form a first target pattern.

Based on the above, in the method of manufacturing the semiconductor structure proposed by the present disclosure, the top-view pattern of the first hard mask pattern is ring-shaped, and the first hard mask pattern has an opening. The second hard mask pattern fills the opening, and the top-view pattern of the second hard mask pattern is completely inside the outer contour of the top-view pattern of the first hard mask pattern. The pattern of the first hard mask pattern and the pattern of the second hard mask pattern are transferred to the material layer to form a first target pattern. Therefore, the manufacturing method of the semiconductor structure proposed by the present disclosure may prevent the deformation of the first target pattern formed through the patterning process. That is to say, with the method for manufacturing the semiconductor structure proposed by the present disclosure, the first target pattern formed through the patterning process may meet expectations. In addition, since the first target pattern may meet expectations, the process margin of the subsequent process may be improved.

### BRIEF DESCRIPTION OF THE DRAWINGS

FIG. 1A to FIG. 1F are partial cross-sectional views of a manufacturing method of a semiconductor structure according to some embodiments of the present disclosure.

### DESCRIPTION OF THE EMBODIMENTS

Embodiments are listed below and described in detail with accompanying drawings, but the provided embodiments are not intended to limit the scope of the present disclosure. In order to facilitate understanding, the same components will be described with the same labels in the following description. In addition, the drawings are for illustrative purposes only and are not drawn to original scale. In fact, the dimensions of the various features may be arbitrarily increased or reduced for clarity of statements.

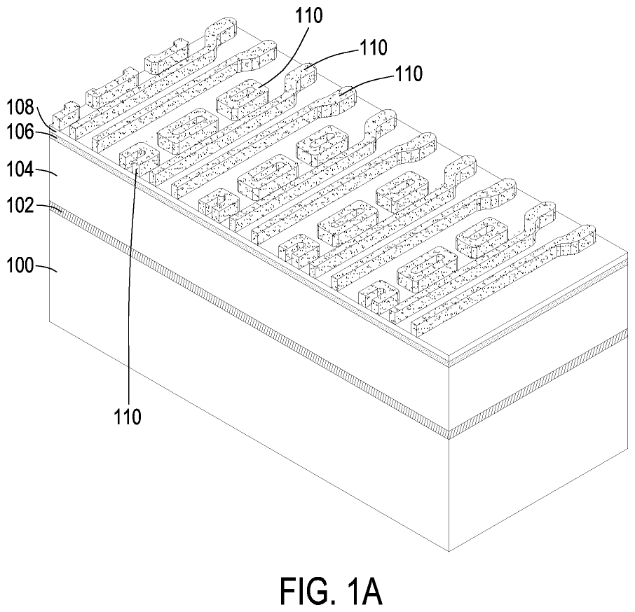

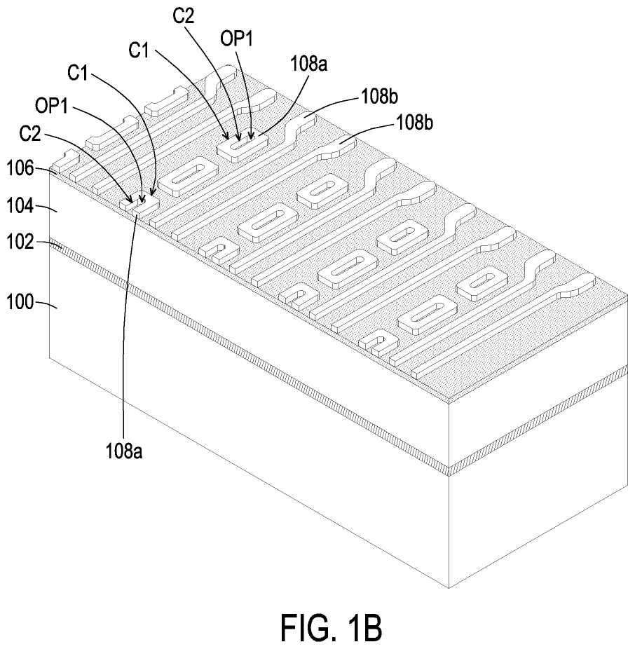

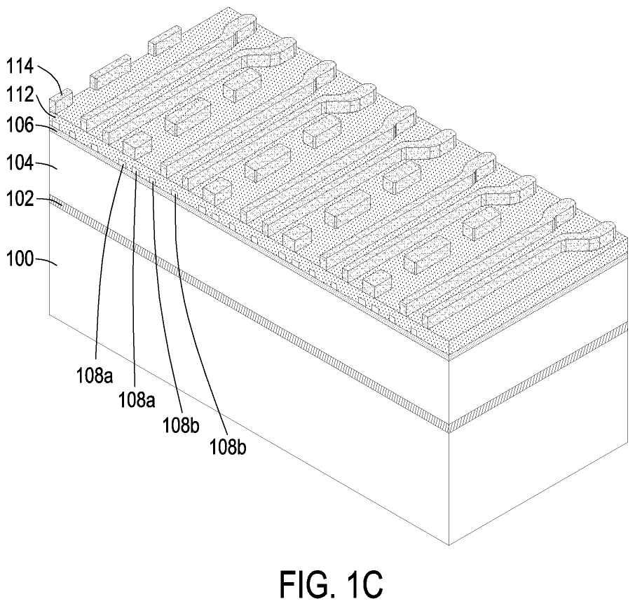

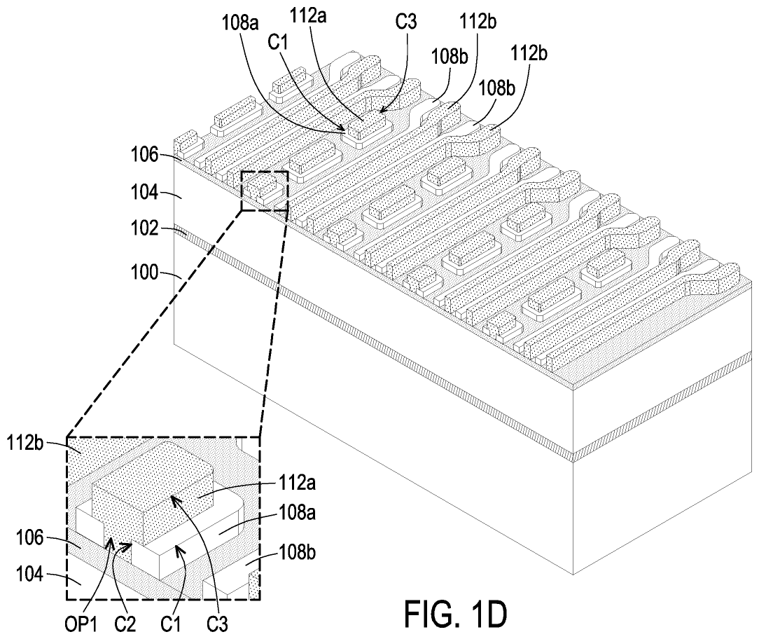

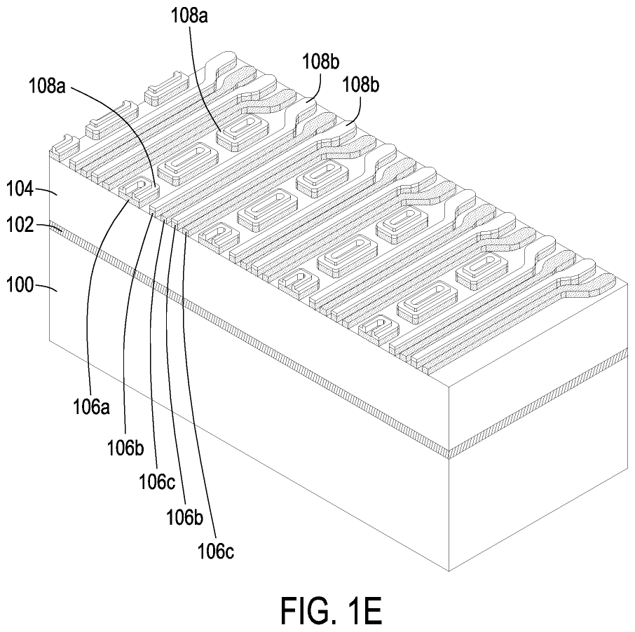

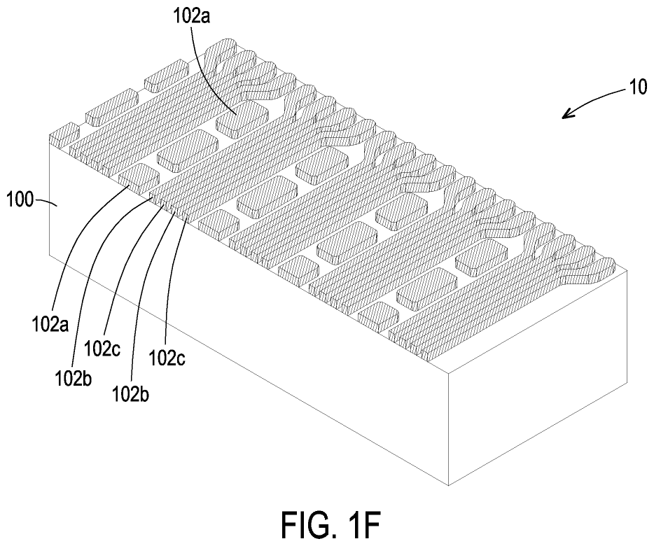

FIG. 1A to FIG. 1F are partial cross-sectional views of a manufacturing method of a semiconductor structure according to some embodiments of the present disclosure. Referring to FIG. 1A, a substrate 100 is provided. The substrate 100 may be a semiconductor substrate, such as silicon substrate. In addition, although not shown in the figure, required components (such as active devices, dielectric layers, interconnect structures or combinations thereof) may be formed on the substrate 100. Next, a material layer 102 is formed on the substrate 100. In this embodiment, the material layer 102 may be a film layer to pattern. The material layer 102 may be a single-layered structure or a multi-layered structure. In some embodiments, the material of the material layer 102 may be conductive material, dielectric material, or semiconductor material. The material layer 102 is formed by, for example, chemical vapor deposition (CVD) or physical vapor deposition (PVD). In this embodiment, conductive material is taken as an example of the material of the material layer 102, but the disclosure is not limited thereto. In some embodiments, the conductive material is, for instance, tungsten, titanium, titanium nitride or combinations thereof.

Next, a hard mask layer 104 may be formed on the material layer 102. The hard mask layer 104 may be a single-layered structure or a multi-layered structure. In some embodiments, the material of the hard mask layer 104 is, for example, a highly selective and transparent film (HST), silicon nitride, spin on carbon (SOC), silicon oxynitride or a combination thereof. The forming method of the hard mask layer 104 is, for example, CVD, spin coating or a combination thereof. A hard mask layer 106 may then be formed on the material layer 102. In some embodiments, a hard mask layer 106 may be formed on a hard mask layer 104. The material of the hard mask layer 106 is, for example, silicon oxide. The forming method of the hard mask layer 106 is, for example, CVD.

Next, a hard mask layer 108 may be formed on the material layer 102. In some embodiments, hard mask layer 108 may be formed on the hard mask layer 106. The material of the hard mask layer 108 is, for instance, polysilicon. The forming method of the hard mask layer 108 is, for example, CVD.

Furthermore, a patterned photoresist layer 110 may be formed on the hard mask layer 108. The patterned photoresist layer 110 may expose a portion of the hard mask layer 108. In some embodiments, the patterned photoresist layer 110 may be formed by a photolithography process.

Referring to FIG. 1B, the hard mask layer 108 may be patterned by using the patterned photoresist layer 110 as a mask to form a hard mask pattern 108a. Thereby, the hard mask pattern 108a may be formed on the material layer 102. In some embodiments, the hard mask pattern 108a may be formed on the hard mask layer 106. The top-view pattern of the hard mask pattern 108a is ring-shaped. The hard mask pattern 108a has an opening OP1. The top-view pattern of the hard mask pattern 108a may have an outer contour C1 and an inner contour C2. The outer contour C1 may surround the inner contour C2. In some embodiments, the opening OP1 may penetrate through the hard mask pattern 108a to expose a portion of the hard mask layer 106. The material of the hard mask pattern 108a is, for example, polysilicon. The hard mask pattern 108a may also be referred to as the first exploded pattern of LELE.

In the embodiment, the number of hard mask patterns 108a may be multiple, but the disclosure is not limited thereto. It is considered to fall within the scope of the present disclosure as long as the number of the hard mask pattern 108a is at least one. In some embodiments, the plurality of hard mask patterns 108a may have the same or different shapes and/or sizes. In addition, the shape and/or size of the hard mask pattern 108a may be adjusted according to product requirements. It is considered to fall within the scope of the present disclosure as long as the top-view pattern of the hard mask pattern 108a is ring-shaped and the hard mask pattern 108a has an opening OP1.

In some embodiments, during the process of forming the hard mask pattern 108a, the hard mask pattern 108b may be formed simultaneously. For example, the patterned photoresist layer 110 may be used as a mask to remove part of the hard mask layer 108 to pattern the hard mask layer 108 to form the hard mask pattern 108a and the hard mask pattern 108b. In some embodiments, the removal method of part of the hard mask layer 108 is, for example, dry etching. The hard mask pattern 108a and the hard mask pattern 108b may be separated from each other. In some embodiments, the top-view pattern of the hard mask pattern 108b may be in the shape of a strip. The material of the hard mask pattern 108b is, for example, polysilicon.

In this embodiment, the number of hard mask patterns 108b may be multiple, but the disclosure is not limited thereto. It is considered to fall within the scope of the present disclosure as long as the number of the hard mask pattern 108b is at least one. In some embodiments, the plurality of hard mask patterns 108b may have the same or different shapes and/or sizes. In addition, those skilled in the art may adjust the shape and/or size of the hard mask pattern 108b according to product requirements.

Next, the patterned photoresist layer 110 may be removed. In some embodiments, the removal method of the patterned photoresist layer 110 is, for example, a method of dry stripping or a method of wet stripping.

Referring to FIG. 1C, a hard mask layer 112 may be formed on the hard mask pattern 108a. In some embodiments, the hard mask layer 112 may be further formed on the hard mask pattern 108b. The hard mask layer 112 may fill the opening OP1. The hard mask layer 112 may be a single-layered structure or a multi-layered structure. In some embodiments, the material of the hard mask layer 112 is, for example, spin on carbon (SOC), spin on silicon anti-reflection coating (SOSA), or a combination thereof. A method for forming the hard mask layer 112 is, for example, a method of spin coating. Next, a patterned photoresist layer 114 may be formed on the hard mask layer 112. The patterned photoresist layer 114 may expose a portion of the hard mask layer 112. The patterned photoresist layer 114 may be formed by a photolithography process.

Referring to FIG. 1D, the hard mask layer 112 may be patterned by using the patterned photoresist layer 114 as a mask to form a hard mask pattern 112a. Thereby, the hard mask pattern 112a may be formed on the hard mask pattern 108a. The hard mask pattern 112a fills the opening OP1. The top-view pattern of the hard mask pattern 112a is completely inside the outer contour C1 of the top-view pattern of the hard mask pattern 108a. That is, the outer contour C1 of the top-view pattern of the hard mask pattern 108a may surround the contour C3 of the top-view pattern of the hard mask pattern 112a. In some embodiments, the contour C3 of the top-view pattern of the hard mask pattern 112a may be located between the outer contour C1 and the inner contour C2 of the top-view pattern of the hard mask pattern 108a. In some embodiments, the inner contour C2 of the top-view pattern of the hard mask pattern 108a may be completely inside the contour C3 of the top-view pattern of the hard mask pattern 112a. That is, the contour C3 of the top-view pattern of the hard mask pattern 112a may surround the inner contour C2 of the top-view pattern of the hard mask pattern 108a. The hard mask pattern 112a may also be referred to as a second exploded pattern of LELE.

In some embodiments, during the process of forming the hard mask pattern 112a, the hard mask pattern 112b may be formed simultaneously. For example, the patterned photoresist layer 114 may be used as a mask to remove part of the hard mask layer 112 to pattern the hard mask layer 112 to form the hard mask pattern 112a and the hard mask pattern 112b. In some embodiments, the removal method of part of the hard mask layer 112 is, for example, dry etching.

The hard mask pattern 112a and the hard mask pattern 112b may be separated from each other. In some embodiments, the hard mask pattern 112b and the hard mask pattern 108a may be separated from each other. In some embodiments, the hard mask pattern 112b and the hard mask pattern 108b may be separated from each other. In some embodiments, the top-view pattern of the hard mask pattern 112b may be in the shape of a strip.

Next, the patterned photoresist layer 114 may be removed. In some embodiments, the removal method of the patterned photoresist layer 114 is, for example, a method of dry stripping or a method of wet stripping.

Referring to FIG. 1E, the patterns of the hard mask pattern 108a and the hard mask pattern 112a may be transferred to the hard mask layer 106 to form the hard mask pattern 106a. The top-view pattern of the hard mask pattern 106a may correspond to the top-view pattern formed by superimposing the top-view pattern of the hard mask pattern 108a and the top-view pattern of the hard mask pattern 112a. In some embodiments, the top-view pattern of the hard mask pattern 106a may be approximately rectangular, but the disclosure is not limited thereto. In this article, “approximately rectangular shape” refers to a shape in which four right corners of a rectangle are changed to rounded corners. In the embodiment, the number of the hard mask patterns 106a may be multiple, but the disclosure is not limited thereto. It is considered to fall within the scope of the present disclosure as long as the number of the hard mask pattern 106a is at least one.

In some embodiments, the pattern of the hard mask pattern 108b and the pattern of the hard mask pattern 112b may be transferred to the hard mask layer 106 to form the hard mask pattern 106b corresponding to the hard mask pattern 108b and the hard mask pattern 106c corresponding to the hard mask pattern 112b. In some embodiments, during the process of forming the hard mask pattern 106a, the hard mask pattern 106b and the hard mask pattern 106c may be formed simultaneously. For example, the hard mask layer 106 may be patterned by using the hard mask pattern 108a, the hard mask pattern 112a, the hard mask pattern 108b, and the hard mask pattern 112b as masks to remove part of the hard mask layer 106, and form a hard mask pattern 106a, a hard mask pattern 106b, and a hard mask pattern 106c. A method for removing part of the hard mask layer 106 is, for example, dry etching. The hard mask pattern 106a, the hard mask pattern 106b and the hard mask pattern 106c may be separated from one another.

In some embodiments, during the process of transferring the patterns of the hard mask pattern 108a and the hard mask pattern 112a to the hard mask layer 106, part of the hard mask pattern 108a may be removed such that the cross-sectional shape of the hard mask pattern 108a may include a stepped shape. In some embodiments, during the process of transferring the pattern of the hard mask pattern 108b to the hard mask layer 106, part of the hard mask pattern 108b may be removed, which reduces the height of the hard mask pattern 108b.

In some embodiments, the hard mask pattern 112a may be removed after the hard mask pattern 106a is formed. In some embodiments, the hard mask pattern 112b may be removed after the hard mask pattern 106c is formed. In some embodiments, the hard mask pattern 112a and the hard mask pattern 112b may be removed simultaneously by the same process. In some embodiments, the removal method of the hard mask pattern 112a and the hard mask pattern 112b is, for example, a method of drying etching.

Referring to FIG. 1F, the pattern of the hard mask pattern 106a may be transferred to the material layer 102 to form the semiconductor structure 10 with the target pattern 102a. The top-view pattern of the target pattern 102a may correspond to the top-view pattern of the hard mask pattern 106a. With the method of this embodiment, the pattern of the hard mask pattern 108a and the pattern of the hard mask pattern 112a may be transferred to the material layer 102 through the LELE technique, so as to form the target pattern 102a. The top-view pattern of the target pattern 102a may correspond to the top-view pattern formed by superimposing the top-view pattern of the hard mask pattern 108a and the top-view pattern of the hard mask pattern 112a. In some embodiments, the top-view pattern of the target pattern 102a may be approximately rectangular, but the disclosure is not limited thereto.

In some embodiments, when the material of the target pattern 102a is conductive material, the target pattern 102a may be used as a contact pad (e.g., a landing pad), but the disclosure is not limited thereto.

In some embodiments, the pattern of the hard mask pattern 106b and the pattern of the hard mask pattern 106c may be transferred to the material layer 102 to form a target pattern 102b corresponding to the hard mask pattern 106b and a target pattern 102c corresponding to the hard mask pattern 106c. In some embodiments, during the process of forming the target pattern 102a, the target pattern 102b and the target pattern 102c may be formed simultaneously. For example, the hard mask pattern 108a, the hard mask pattern 106a, the hard mask pattern 108b, the hard mask pattern 106b, and the hard mask pattern 106c may be used as masks to remove part of the hard mask layer 104 and part of the material layer 102, and the hard mask layer 104 and the material layer 102 are patterned, and the target pattern 102a, the target pattern 102b and the target pattern 102c are formed. In some embodiments, the removal method of part of the hard mask layer 104 and part of the material layer 102 is, for example, a method of dry etching. In some embodiments, the hard mask pattern 108a, the hard mask pattern 106a, the hard mask pattern 108b, the hard mask pattern 106b, the hard mask pattern 106c and the hard mask layer 104 may be removed during the process of forming target pattern 102a, target pattern 102b, and target pattern 102c.

In some embodiments, when the material of the target pattern 102b and the target pattern 102c are conductive material, the target pattern 102b and the target pattern 102c may be used as wires, but the disclosure is not limited thereto.

In the embodiment, the pattern of the hard mask pattern 108a, the pattern of the hard mask pattern 112a, the pattern of the hard mask pattern 108b and the pattern of the hard mask pattern 112b may be transferred to the hard mask layer 106, the hard mask layer 104 and the material layer 102 by etching process (e.g., a process of dry etching), but the disclosure is not limited thereto. In other embodiments, part of the film layers in the above-mentioned embodiments may be omitted according to requirements. For example, the hard mask layer 104 may be omitted, and the pattern of the hard mask pattern 108a, the pattern of the hard mask pattern 112a, the pattern of the hard mask pattern 108b and the pattern of the hard mask pattern 112b may be transferred to the hard mask layer 106 and the material layer 102 by etching process (e.g., a process of dry etching). In other embodiments, the hard mask layer 104 and the hard mask layer 106 may be omitted, and the pattern of the hard mask pattern 108a, the pattern of the hard mask pattern 112a, the pattern of the hard mask pattern 108b and the pattern of the hard mask pattern 112b may be transferred to the material layer 102 by etching process (e.g., a process of dry etching).

Based on the above-mentioned embodiments, the top-view pattern of the hard mask pattern 108a is ring-shaped, and the hard mask pattern 108a has an opening OP1. The hard mask pattern 112a fills the opening OP1, and the top-view pattern of the hard mask pattern 112a is completely inside the outer contour C1 of the top-view pattern of the hard mask pattern 108a. The superposition of the pattern of the hard mask pattern 108a and the pattern of the hard mask pattern 112a is transferred to the material layer 102 to form the target pattern 102a. Therefore, the position of the superposition of the two rougher patterns is not at the edge of the target pattern 102a, and the manufacturing method of the present embodiment may prevent the semiconductor structure fabricated by the LELE technique from forming a concave contour. That is to say, by the above-mentioned manufacturing method of the semiconductor structure 10, the target pattern 102a of the semiconductor structure manufactured by the LELE technique may meet expectations. In addition, since the target pattern 102a may meet expectations, the process margin of the subsequent process may be improved. In addition, when the material of the target pattern 102a is conductive material, the contact resistance may be reduced by the above-mentioned manufacturing method of the semiconductor structure 10.

The present disclosure is suitable for making miniaturized semiconductor structures to increase the total number of dies on a wafer. Therefore, the present disclosure may reduce the production cost and energy consumption of manufacturing a single IC, and reduce the production energy consumption of subsequent packaging, thereby reducing carbon emissions in the production process of semiconductor structures. Furthermore, the present disclosure provides a green semiconductor technology with the improved reliability and durability.

Although the present disclosure has been disclosed above with the embodiments, it is not intended to limit the present disclosure. Those skilled in the art may make some changes and modifications without departing from the spirit and scope of the present disclosure. The scope of protection of the present disclosure should be defined by the scope of the appended patent disclosure.

What is claimed is:

1. A method for manufacturing a semiconductor structure, comprising:
providing a substrate;
forming a material layer on the substrate;
forming a first hard mask pattern on the material layer, wherein a top-view pattern of the first hard mask pattern is ring-shaped, and the first hard mask pattern has an opening;
forming a second hard mask pattern on the first hard mask pattern, wherein the second hard mask pattern fills the opening, and a top-view pattern of the second hard mask pattern is completely inside an outer contour of the top-view pattern of the first hard mask pattern, wherein a contour of the top-view pattern of the second hard mask pattern is located between the outer contour of the top-view pattern of the first hard mask pattern and an inner contour of the top-view pattern of the first hard mask pattern; and
transferring a pattern of the first hard mask pattern and a pattern of the second hard mask pattern to the material layer to form a first target pattern.

2. The method of manufacturing the semiconductor structure of claim 1, wherein the contour of the top-view pattern of the second hard mask pattern surrounds the inner contour of the top-view pattern of the first hard mask pattern.

3. The method for manufacturing the semiconductor structure of claim 1, wherein the opening penetrates the first hard mask pattern.

4. The method for manufacturing the semiconductor structure of claim 1, wherein the method for forming the first hard mask pattern comprises:
forming a hard mask layer on the material layer;
forming a patterned photoresist layer on the hard mask layer; and
patterning the hard mask layer to form the first hard mask pattern by using the patterned photoresist layer as a mask.

5. The method for manufacturing the semiconductor structure of claim 1, wherein the method for forming the second hard mask pattern comprises:
forming a hard mask layer on the first hard mask pattern, wherein the hard mask layer fills the opening;
forming a patterned photoresist layer on the hard mask layer; and
patterning the hard mask layer to form the second hard mask pattern by using the patterned photoresist layer as a mask.

6. The method for manufacturing the semiconductor structure of claim 1, wherein a top-view pattern of the first target pattern corresponds to a top-view pattern formed by superimposing the top-view pattern of the first hard mask pattern and the top-view pattern of the second hard mask pattern.

7. The method for manufacturing the semiconductor structure of claim 1, further comprising:
forming a hard mask layer on the material layer prior to forming the first hard mask pattern.

8. The method for manufacturing the semiconductor structure of claim 7, wherein the method of transferring the pattern of the first hard mask pattern and the pattern of the second hard mask pattern to the material layer comprises:
transferring the pattern of the first hard mask pattern and the pattern of the second hard mask pattern to the hard mask layer to form a third hard mask pattern; and
transferring the pattern of the third hard mask pattern to the material layer to form the first target pattern.

9. The method for manufacturing the semiconductor structure of claim 8, wherein a top-view pattern of the third hard mask pattern corresponds to a top-view pattern formed by superimposing the top-view pattern of the first hard mask pattern and the top-view pattern of the second hard mask pattern.

10. The method for manufacturing the semiconductor structure of claim 8, wherein in the process of transferring the pattern of the first hard mask pattern and the pattern of the second hard mask pattern to the hard mask layer, a part of the first hard mask pattern is removed, so that a cross-sectional shape of the first hard mask pattern comprises a step shape.

11. The method for manufacturing the semiconductor structure of claim 8, further comprising:
removing the second hard mask pattern after the third hard mask pattern is formed.

12. The method for manufacturing the semiconductor structure of claim 8, further comprising:
forming a fourth hard mask pattern simultaneously in the process of forming the first hard mask pattern, wherein the first hard mask pattern and the fourth hard mask pattern are separated from each other.

13. The method for manufacturing the semiconductor structure of claim 12, wherein a top-view pattern of the fourth hard mask pattern is in a shape of a strip.

14. The method for manufacturing the semiconductor structure of claim 12, further comprising:
transferring a pattern of the fourth hard mask pattern to the hard mask layer to form a fifth hard mask pattern corresponding to the fourth hard mask pattern, wherein the third hard mask pattern and the fifth hard mask pattern are separated from each other; and
transferring a pattern of the fifth hard mask pattern to the material layer to form a second target pattern corresponding to the fifth hard mask pattern.

15. The method for manufacturing the semiconductor structure of claim 8, further comprising:
forming a fourth hard mask pattern simultaneously in the process of forming the second hard mask pattern, wherein the second hard mask pattern and the fourth hard mask pattern are separated from each other.

16. The method for manufacturing the semiconductor structure of claim 15, wherein a top-view pattern of the fourth hard mask pattern is in a shape of a stripe.

17. The method for manufacturing the semiconductor structure of claim 15, further comprising:
transferring a pattern of the fourth hard mask pattern to the hard mask layer to form a fifth hard mask pattern corresponding to the fourth hard mask pattern, wherein the third hard mask pattern and the fifth hard mask pattern are separated from each other; and
transferring a pattern of the fifth hard mask pattern to the material layer to form a second target pattern corresponding to the fifth hard mask pattern.

18. The method for manufacturing the semiconductor structure of claim 8, further comprising:
forming a fourth hard mask pattern simultaneously in the process of forming the first hard mask pattern, wherein the first hard mask pattern and the fourth hard mask pattern are separated from each other; and
forming a fifth hard mask pattern simultaneously in the process of forming the second hard mask pattern, wherein the second hard mask pattern and the fifth hard mask pattern are separated from each other.

19. The method for manufacturing the semiconductor structure of claim 18, further comprising:
transferring a pattern of the fourth hard mask pattern and a pattern of the fifth hard mask pattern to the hard mask layer to form a sixth hard mask pattern corresponding to the fourth hard mask pattern and a seventh hard mask pattern corresponding to the fifth hard mask pattern, wherein the third hard mask pattern, the sixth hard mask pattern and the seventh hard mask pattern are separated from one another; and
transferring a pattern of the sixth hard mask pattern and a pattern of the seventh hard mask pattern to the material layer to form a second target pattern corresponding to the sixth hard mask pattern and a third target pattern corresponding to the seventh hard mask pattern.
